(19) United States
(12) Patent Application Publication
(10) Pub. No.: US 2026/0075972 A1
(43) Pub. Date: Mar. 12, 2026

(54) Electronic Device with Infrared Transparent and Visibly Opaque Coating

(71) Applicant: Apple Inc., Cupertino, CA (US)

(72) Inventors: Hannah A. Maret, San Francisco, CA (US); Tyler R. Roschuk, Morgan Hill, CA (US); Marta M. Giachino, Sausalito, CA (US); Matthew S. Rogers, San Jose, CA (US); Andrej Halabica, Cupertino, CA (US); Ligang Wang, San Jose, CA (US); Adam R. Kohn, San Francisco, CA (US); Jun Li, Huizhou (CN); Yuanqing Han, Beijing (CN)

(21) Appl. No.: 19/000,150

(22) Filed: Dec. 23, 2024

Related U.S. Application Data
(60) Provisional application No. 63/691,928, filed on Sep. 6, 2024.

(51) Int. Cl. H10F 39/00

(52) U.S. Cl. CPC H10F 39/8057; H10F 39/804

(57) ABSTRACT

An electronic device may be provided with a visible and infrared transparent cover layer. The electronic device may include infrared devices that operate on infrared light passing through the cover layer. One or more infrared transparent and visibly opaque ink layers may be disposed on the cover layer overlapping the infrared devices. An optional infrared antireflective coating may be layered onto the infrared transparent and visibly opaque ink layer(s). The ink layer(s) may pass the infrared light while blocking visible light to help hide the infrared devices from view. Layering the ink layer(s) onto the cover layer may cause the cover layer to be less brittle than when a physical vapor deposition (PVD) coating is layered directly onto the cover layer.

This application claims the benefit of U.S. Provisional Ser. No. 63/691,928, filed Sep. 6, 2024, which is hereby incorporated by reference herein in its entirety.

### FIELD

This relates generally to coatings for electronic devices, including coatings for optically transparent electronic device structures.

### BACKGROUND

Electronic devices such as cellular telephones, computers, watches, and other devices contain electronic device structures. An electronic device structure can be provided with a coating. The coating can impact one or more optical properties of the electronic device structure.

It can be challenging to provide a coating that imparts the electronic device structure with desired optical characteristics over a range of different wavelengths. In addition, if care is not taken, the coating can cause the electronic device structure to become excessively brittle and prone to damage.

### SUMMARY

An electronic device may be provided with a housing and a display mounted to the housing. The display may include a display cover layer. The display may include an active area that surrounds an inactive island. An infrared sensor and an infrared emitter may be aligned with the inactive island. The infrared sensor and the infrared emitter may operate on infrared light that passes through the display cover layer within the inactive island.

The display cover layer may be provided with one or more infrared transparent and visibly opaque ink layers overlapping the infrared sensor and the infrared emitter in the inactive island. If desired, an infrared antireflective coating may be layered onto the infrared transparent and visibly opaque ink layer(s). The infrared antireflective coating may be formed from a multi-layer thin-film interference filter, for example. The infrared antireflective coating may include a gap between the infrared sensor and the infrared emitter to minimize cross-talk. The infrared transparent and visibly opaque ink layer(s) may help to hide the infrared sensor and the infrared emitter from view while still allowing the infrared sensor to gather sensor data through the display cover layer. The infrared transparent and visibly opaque ink layers may cause the display cover layer to become less brittle than when a multi-layer physical vapor deposition (PVD) coating is deposited directly onto the display cover layer.

### BRIEF DESCRIPTION OF THE DRAWINGS

FIG. 1 is a perspective view of an illustrative electronic device that may be provided with an infrared transparent and visibly opaque coating in accordance with some embodiments.

FIG. 2 is a schematic diagram of illustrative circuitry in an electronic device in accordance with some embodiments.

FIG. 3 is a cross-sectional side view of an illustrative infrared transparent and visibly opaque coating stack for an infrared device in an electronic device in accordance with some embodiments.

FIG. 4 is a cross-sectional side view of an illustrative electronic device having an infrared transparent and visibly opaque coating stack overlapping an infrared emitter and an infrared sensor in accordance with some embodiments.

FIG. 5 is an exploded perspective view of an illustrative infrared transparent and visibly opaque coating stack in accordance with some embodiments.

FIG. 6 is a cross-sectional side view of an illustrative infrared antireflective coating in an infrared transparent and visibly opaque coating stack in accordance with some embodiments.

FIG. 7 is a plot of light transmission as a function of wavelength for illustrative infrared transparent and visibly opaque ink layer(s) in an infrared transparent and visibly opaque coating stack in accordance with some embodiments.

### DETAILED DESCRIPTION

An electronic device may be provided with a visible and infrared transparent cover layer such as a display cover layer. The device may include infrared devices that convey infrared light through the visible and infrared transparent cover layer. A coating stack may be layered onto an inner surface of the visible and infrared transparent cover layer and overlapping the infrared devices. The coating stack may include one or more infrared transparent and visibly opaque ink layers on the visible and infrared transparent cover layer. An optional infrared antireflective coating may be layered onto the infrared transparent and visibly opaque ink layer(s). The coating stack may pass the infrared light while blocking visible light to help hide the infrared devices from view. Layering the infrared transparent and visibly opaque ink layer(s) on the visible and infrared transparent cover layer may cause the visible and infrared transparent cover layer to be less brittle than in implementations where a physical vapor deposition (PVD) coating is layered directly onto the visible and infrared transparent cover layer.

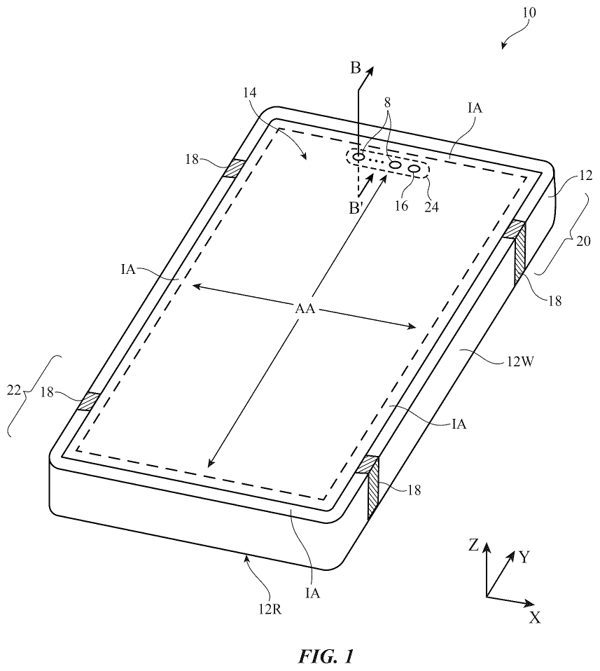

FIG. 1 is a perspective view of an illustrative electronic device 10 that may be provided with an infrared (IR) transparent and visibly opaque coating stack. Device 10 may be a portable electronic device or other suitable electronic device. For example, device 10 may be a laptop computer, a tablet computer, may be a somewhat smaller device such as a wrist-watch device, pendant device, headphone device, earpiece device, headset device (e.g., virtual, augmented, or mixed reality glasses or goggles), ring device, or another wearable or miniature device, may be a handheld device such as a cellular telephone, a media player, or may be another small portable device. Device 10 may also be a set-top box, a speaker device, a desktop computer, a display into which a computer or other processing circuitry has been integrated, a display without an integrated computer, a gaming controller, a computer stylus, a keyboard device, a trackpad device, a mouse, or another type of peripheral device or accessory device, a wireless access point, a wireless base station, an electronic device incorporated into a kiosk, building, or vehicle, or other suitable electronic equipment. In the illustrative configuration shown in FIG. 1, device 10 forms a cellular telephone, tablet computer, wristwatch device, or another device having a substantially rectangular outline. This is illustrative and non-limiting.

Device 10 may include a housing such as housing 12. Housing 12, which may sometimes be referred to as a case, may be formed of plastic, glass, ceramics, fiber composites, metal (e.g., stainless steel, aluminum, etc.), other suitable materials, or a combination of these materials. In some situations, parts of housing 12 may be formed from dielectric or other low-conductivity material (e.g., glass, ceramic, plastic, sapphire, etc.). In other situations, housing 12 or at least some of the structures that make up housing 12 may be formed from metal elements.

Device 10 may, if desired, include a display such as display 14. Display 14 may be mounted on the front face of device 10. Display 14 may be a touch screen that incorporates capacitive touch electrodes or may be insensitive to touch. The rear face of housing 12 (i.e., the face of device 10 opposing the front face of device 10) may have a substantially planar housing wall such as rear housing wall 12R (e.g., a planar housing wall). Rear housing wall 12R may have slots that pass entirely through the rear housing wall and that therefore separate portions of housing 12 from each other. Rear housing wall 12R may include conductive portions and/or dielectric portions. If desired, rear housing wall 12R may include a planar metal layer covered by a thin layer or coating of dielectric such as glass, plastic, sapphire, or ceramic (e.g., a dielectric cover layer). Housing 12 may also have shallow grooves that do not pass entirely through housing 12. The slots and grooves may be filled with plastic or other dielectric materials. If desired, portions of housing 12 that have been separated from each other (e.g., by a through slot) may be joined by internal conductive structures (e.g., sheet metal or other metal members that bridge the slot).

Housing 12 may include peripheral housing structures such as peripheral structures 12W. Conductive portions of peripheral structures 12W and conductive portions of rear housing wall 12R may sometimes be referred to herein collectively as conductive structures of housing 12. Peripheral structures 12W may run around the periphery of device 10 and display 14. In configurations in which device 10 and display 14 have a rectangular shape with four edges, peripheral structures 12W may be implemented using peripheral housing structures that have a rectangular ring shape with four corresponding edges and that extend from rear housing wall 12R to the front face of device 10 (as an example). In other words, device 10 may have a length (e.g., measured parallel to the Y-axis), a width that is less than the length (e.g., measured parallel to the X-axis), and a height (e.g., measured parallel to the Z-axis) that is less than the width. Peripheral structures 12W or part of peripheral structures 12W may serve as a bezel for display 14 (e.g., a cosmetic trim that surrounds all four sides of display 14 and/or that helps hold display 14 to device 10) if desired. Peripheral structures 12W may, if desired, form sidewall structures for device 10 (e.g., by forming a metal band with vertical sidewalls, curved sidewalls, etc.).

Peripheral structures 12W may be formed from a conductive material such as metal and may therefore sometimes be referred to as peripheral conductive housing structures, conductive housing structures, peripheral metal structures, peripheral conductive sidewalls, peripheral conductive sidewall structures, conductive housing sidewalls, peripheral conductive housing sidewalls, sidewalls, sidewall structures, or a peripheral conductive housing member (as examples). Peripheral conductive housing structures 12W may be formed from a metal such as stainless steel, aluminum, alloys, or other suitable materials. One, two, or more than two separate structures may be used in forming peripheral conductive housing structures 12W.

It is not necessary for peripheral conductive housing structures 12W to have a uniform cross-section. For example, the top portion of peripheral conductive housing structures 12W may, if desired, have an inwardly protruding ledge that helps hold display 14 in place. The bottom portion of peripheral conductive housing structures 12W may also have an enlarged lip (e.g., in the plane of the rear surface of device 10). Peripheral conductive housing structures 12W may have substantially straight vertical sidewalls, may have sidewalls that are curved, or may have other suitable shapes. In some configurations (e.g., when peripheral conductive housing structures 12W serve as a bezel for display 14), peripheral conductive housing structures 12W may run around the lip of housing 12 (i.e., peripheral conductive housing structures 12W may cover only the edge of housing 12 that surrounds display 14 and not the rest of the sidewalls of housing 12).

Rear housing wall 12R may lie in a plane that is parallel to display 14. In configurations for device 10 in which some or all of rear housing wall 12R is formed from metal, it may be desirable to form parts of peripheral conductive housing structures 12W as integral portions of the housing structures forming rear housing wall 12R. For example, rear housing wall 12R of device 10 may include a planar metal structure and portions of peripheral conductive housing structures 12W on the sides of housing 12 may be formed as flat or curved vertically extending integral metal portions of the planar metal structure (e.g., housing structures 12R and 12W may be formed from a continuous piece of metal in a unibody configuration). Housing structures such as these may, if desired, be machined from a block of metal and/or may include multiple metal pieces that are assembled together to form housing 12. Rear housing wall 12R may have one or more, two or more, or three or more portions. Peripheral conductive housing structures 12W and/or conductive portions of rear housing wall 12R may form one or more exterior surfaces of device 10 (e.g., surfaces that are visible to a user of device 10) and/or may be implemented using internal structures that do not form exterior surfaces of device 10 (e.g., conductive housing structures that are not visible to a user of device 10 such as conductive structures that are covered with layers such as thin cosmetic layers, protective coatings, and/or other coating/cover layers that may include dielectric materials such as glass, ceramic, plastic, or other structures that form the exterior surfaces of device 10 and/or serve to hide peripheral conductive housing structures 12W and/or conductive portions of rear housing wall 12R from view of the user).

Display 14 may have an array of pixels that form an active area AA that displays images for a user of device 10. For example, active area AA may include an array of display pixels. The array of pixels may be formed from liquid crystal display (LCD) components, an array of electrophoretic pixels, an array of plasma display pixels, an array of organic light-emitting diode display pixels or other light-emitting diode pixels, an array of electrowetting display pixels, or display pixels based on other display technologies. If desired, active area AA may include touch sensors such as touch sensor capacitive electrodes, force sensors, or other sensors for gathering a user input.

Display 14 may have an inactive border region that runs along one or more of the edges of active area AA. Inactive area IA of display 14 may be free of pixels for displaying images and may overlap circuitry and other internal device structures in housing 12. To block these structures from view by a user of device 10, the underside of the display cover layer or other layers in display 14 that overlap inactive area IA may be coated with an opaque masking layer in inactive area IA. The opaque masking layer may have any suitable color.

If desired, the inactive area IA at upper region 20 of device 10 may include an inactive region such as region 24. Region 24 may be laterally surrounded (e.g., on all sides, on four sides, etc.) by active area AA. Region 24 is sometimes also referred to herein as notch 24 or inactive island 24 in display 14. Region 24 may be surrounded on three sides by active area AA in some implementations (e.g., region 24 may have a fourth side defined by peripheral conductive housing structures 12W).

Active area AA may, for example, be defined by the lateral area of a display module or panel for display 14 (e.g., a display module that includes pixel circuitry, touch sensor circuitry, etc.). Active area AA may display (emit) display light. The display light may contain images (e.g., a video stream of image frames that represent virtual objects, a graphical user interface, video file playback, etc.). The display module may have a recess or notch in upper region 20 of device 10 that is free from active display circuitry (e.g., overlapping region 24). There may, for example, be no active pixels in display 14 within region 24 that emit image for display 14. Region 24 may have a rectangular outline, a circular outline, an elliptical outline, a substantially rectangular outline with rounded edges, or any other desired shape having any desired number of curved and/or straight edges.

Device 10 may include one or more device components aligned with region 24. For example, device 10 may include an image sensor 16 (e.g., a front-facing camera) aligned with region 24. Image sensor 16 may capture images of visible light received through display 14 within region 24. If desired, device 10 may include a phased antenna array aligned with region 24. The phased antenna array may transmit and/or receive radio-frequency signals (e.g., in a millimeter wave frequency band) through display 14 within region 24. If desired, device 10 may include an ambient light sensor within region 24. The ambient light sensor may receive light through display 14 within region 24.

Device 10 may also include one or more IR devices 8 overlapping and/or aligned with region 24. IR devices 8 may include one or more IR emitters (e.g., a dot projector, a flood illuminator, IR light emitting diodes, etc.) that emit IR light through display 14 within region 24. Additionally or alternatively, IR devices 8 may include one or more IR sensors that receive IR light through display 14 within region 24 (e.g., one or more IR cameras having IR image sensor pixels). The IR sensors may capture images of the IR light received through display 14 within region 24.

If desired, control circuitry on device 10 may process the images captured by the IR sensor(s) to identify the proximity between device 10 and one or more objects (e.g., the IR sensor(s) may be IR proximity sensor(s)), to generate a spatial map (e.g., a depth map) between device 10 and one or more points on one or more objects external to device 10, to map and/or detect one or more facial features of a user (e.g., to perform a facial authentication or recognition operation which may, if desired, be used to unlock device 10 for use by the user), and/or to perform any other desired operations. If desired, the images captured by the IR sensor(s) may serve as a user input provided to device 10. Device 10 may perform any desired operations based on IR light emitted by the IR emitter(s) and/or based on IR light received by the IR sensor(s) in IR devices 8.

Display 14 may be protected using a display cover layer such as a layer of transparent glass, clear plastic, transparent ceramic, sapphire, or other transparent crystalline material, or other transparent layer(s). The display cover layer may have a planar shape, a convex curved profile, a shape with planar and curved portions, a layout that includes a planar main area surrounded on one or more edges with a portion that is bent out of the plane of the planar main area, or other suitable shapes. The display cover layer may cover the entire front face of device 10. In another suitable arrangement, the display cover layer may cover substantially all of the front face of device 10 or only a portion of the front face of device 10. Openings may be formed in the display cover layer. For example, an opening may be formed in the display cover layer to accommodate a button and/or a fingerprint sensor. An opening may also be formed in the display cover layer to accommodate ports such as a speaker port and/or a microphone port. Openings may be formed in housing 12 to form communications ports (e.g., an audio jack port, a digital data port, etc.) and/or audio ports for audio components such as a speaker and/or a microphone if desired.

The pixel circuitry in active area AA of display 14 may emit visible light (e.g., containing visible images for view by a user) through the display cover layer (e.g., outside of region 24). The visible light is at visible wavelengths (e.g., in one or more color bands or channels between 400 nm and 700 nm). As used herein, the IR light transmitted by one or more IR emitters in IR devices 8 and/or received by one or more IR sensors in IR devices 8 may include light at near infrared (NIR) wavelengths (e.g., between 700 nm and around 1100 nm), at IR wavelengths that are longer than 1100 nm, and/or at any other desired wavelengths greater than or equal to 700 nm. IR device(s) 8 may operate on and/or convey the IR light through the display cover layer within region 24. As used herein, the term “operate on IR light” means the transmission/emission of IR light and/or the reception/sensing of IR light (e.g., IR device(s) 8 may operate on IR light by only transmitting/emitting the IR light, by only receiving/sensing the IR light, or by both transmitting/emitting and receiving/sensing the IR light). If desired, device 10 may include IR device(s) 8 that emit IR light and/or that receive IR light through other surfaces of device 10 (e.g., through rear housing wall 12R, through a window in peripheral conductive housing structures 12W, etc.).

Display 14 may include conductive structures such as an array of capacitive electrodes for a touch sensor, conductive lines for addressing pixels, driver circuits, etc. Housing 12 may include internal conductive structures such as metal frame members and a planar conductive housing member (sometimes referred to as a conductive support plate or backplate) that spans the walls of housing 12 (e.g., a substantially rectangular sheet formed from one or more metal parts that is welded or otherwise connected between opposing sides of peripheral conductive housing structures 12W). The conductive support plate may form an exterior rear surface of device 10 or may be covered by a dielectric cover layer such as a thin cosmetic layer, protective coating, and/or other coatings that may include dielectric materials such as glass, ceramic, plastic, or other structures that form the exterior surfaces of device 10 and/or serve to hide the conductive support plate from view of the user (e.g., the conductive support plate may form part of rear housing wall 12R). Device 10 may also include conductive structures such as printed circuit boards, components mounted on printed circuit boards, and other internal conductive structures. These conductive structures, which may be used in forming a ground plane in device 10, may extend under active area AA of display 14, for example.

In regions 22 and 20, openings may be formed within the conductive structures of device 10 (e.g., between peripheral conductive housing structures 12W and opposing conductive ground structures such as conductive portions of rear housing wall 12R, conductive traces on a printed circuit board, conductive electrical components in display 14, etc.). These openings, which may sometimes be referred to as gaps, may be filled with air, plastic, and/or other dielectrics and may be used in forming slot antenna resonating elements for one or more antennas in device 10, if desired.

Conductive housing structures and other conductive structures in device 10 may serve as a ground plane for the antennas in device 10. The openings in regions 22 and 20 may serve as slots in open or closed slot antennas, may serve as a central dielectric region that is surrounded by a conductive path of materials in a loop antenna, may serve as a space that separates an antenna resonating element such as a strip antenna resonating element or an inverted-F antenna resonating element from the ground plane, may contribute to the performance of a parasitic antenna resonating element, or may otherwise serve as part of antenna structures formed in regions 22 and 20. If desired, the ground plane that is under active area AA of display 14 and/or other metal structures in device 10 may have portions that extend into parts of the ends of device 10 (e.g., the ground may extend towards the dielectric-filled openings in regions 22 and 20), thereby narrowing the slots in regions 22 and 20. Region 22 may sometimes be referred to herein as lower region 22 or lower end 22 of device 10. Region 20 may sometimes be referred to herein as upper region 20 or upper end 20 of device 10.

In general, device 10 may include any suitable number of antennas (e.g., one or more, two or more, three or more, four or more, etc.). The antennas in device 10 may be located at opposing first and second ends of an elongated device housing (e.g., at lower region 22 and/or upper region 20 of device 10 of FIG. 1), along one or more edges of a device housing, in the center of a device housing, in other suitable locations, or in one or more of these locations. The arrangement of FIG. 1 is illustrative and non-limiting.

Portions of peripheral conductive housing structures 12W may be provided with peripheral gap structures. For example, peripheral conductive housing structures 12W may be provided with one or more dielectric-filled gaps such as gaps 18, as shown in FIG. 1. The gaps in peripheral conductive housing structures 12W may be filled with dielectric such as polymer, ceramic, glass, air, other dielectric materials, or combinations of these materials. Gaps 18 may divide peripheral conductive housing structures 12W into one or more peripheral conductive segments. The conductive segments that are formed in this way may form parts of antennas in device 10 if desired. Other dielectric openings may be formed in peripheral conductive housing structures 12W (e.g., dielectric openings other than gaps 18) and may serve as dielectric antenna windows for antennas mounted within the interior of device 10. Antennas within device 10 may be aligned with the dielectric antenna windows for conveying radio-frequency signals through peripheral conductive housing structures 12W. Antennas within device 10 may also be aligned with inactive area IA of display 14 for conveying radio-frequency signals through display 14.

If desired, device 10 may include one or more upper antennas and one or more lower antennas. An upper antenna may, for example, be formed in upper region 20 of device 10. A lower antenna may, for example, be formed in lower region 22 of device 10. Additional antennas may be formed along the edges of housing 12 extending between regions 20 and 22 if desired. The antennas may be used separately to cover identical communications bands, overlapping communications bands, or separate communications bands. The antennas may be used to implement an antenna diversity scheme or a multiple-input-multiple-output (MIMO) antenna scheme. The example of FIG. 1 is illustrative and non-limiting. If desired, housing 12 may have other shapes (e.g., a square shape, cylindrical shape, spherical shape, combinations of these and/or different shapes, etc.).

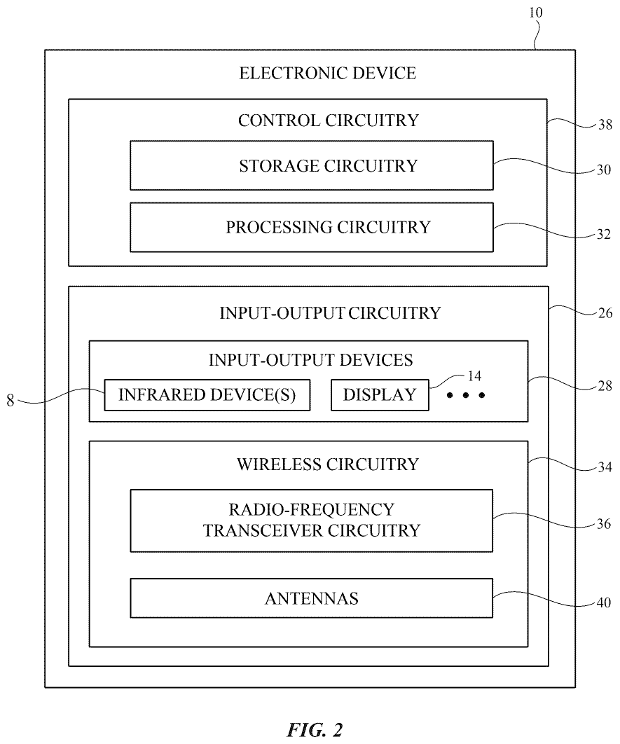

A schematic diagram of illustrative components that may be used in device 10 is shown in FIG. 2. As shown in FIG. 2, device 10 may include control circuitry 38. Control circuitry 38 may include storage such as storage circuitry 30. Storage circuitry 30 may include hard disk drive storage, nonvolatile memory (e.g., flash memory or other electrically-programmable-read-only memory configured to form a solid-state drive), volatile memory (e.g., static or dynamic random-access-memory), etc.

Control circuitry 38 may include processing circuitry such as processing circuitry 32. Processing circuitry 32 may be used to control the operation of device 10. Processing circuitry 32 may include one or more processors such as microprocessors, microcontrollers, digital signal processors, host processors, baseband processor integrated circuits, application specific integrated circuits, graphics processing units, central processing units (CPUs), etc. Control circuitry 38 may be configured to perform operations in device 10 using hardware (e.g., dedicated hardware or circuitry), firmware, and/or software. Software code for performing operations in device 10 may be stored on storage circuitry 30 (e.g., storage circuitry 30 may include non-transitory (tangible) computer readable storage media that stores the software code). The software code may sometimes be referred to as program instructions, software, data, instructions, or code. Software code stored on storage circuitry 30 may be executed by processing circuitry 32.

Control circuitry 38 may be used to run software on device 10 such as internet browsing applications, voice-over-internet-protocol (VOIP) telephone call applications, email applications, media playback applications, operating system functions, etc. To support interactions with external equipment, control circuitry 38 may be used in implementing communications protocols. Communications protocols that may be implemented using control circuitry 38 include internet protocols, wireless local area network protocols (e.g., IEEE 802.11 protocols—sometimes referred to as Wi-Fi®), protocols for other short-range wireless communications links such as the Bluetooth® protocol or other WPAN protocols, IEEE 802.11ad protocols, cellular telephone protocols, MIMO protocols, antenna diversity protocols, satellite navigation system protocols, antenna-based spatial ranging protocols (e.g., radio detection and ranging (RADAR) protocols or other desired range detection protocols for signals conveyed at millimeter and centimeter wave frequencies), etc. Each communication protocol may be associated with a corresponding radio access technology (RAT) that specifies the physical connection methodology used in implementing the protocol.

Device 10 may include input-output circuitry 26. Input-output circuitry 26 may include input-output devices 28. Input-output devices 28 may be used to allow data to be supplied to device 10 and to allow data to be provided from device 10 to external devices. Input-output devices 28 may include IR device(s) 8 and display 14, as examples. IR device(s) 8 may, if desired, include front-facing optical devices that emit IR light and/or that gather IR sensor data (e.g., images of incident IR light) through display 14. If desired, IR device(s) 8 may include rear-facing optical devices that emit IR light and/or that gather IR sensor data through rear housing wall 12R of device 10 (FIG. 1).

If desired, input-output devices 28 may also include user interface devices, data port devices, sensors, and other input-output components. For example, input-output devices 28 may include touch screens, displays without touch sensor capabilities, buttons, joysticks, scrolling wheels, touch pads, key pads, keyboards, microphones, cameras, speakers, status indicators, light sources, audio jacks and other audio port components, digital data port devices, light sensors, gyroscopes, accelerometers or other components that can detect motion and device orientation relative to the Earth, capacitance sensors, proximity sensors (e.g., a capacitive proximity sensor and/or an infrared proximity sensor), magnetic sensors, and other sensors and input-output components.

Input-output circuitry 26 may include wireless circuitry such as wireless circuitry 34 for wirelessly conveying radio-frequency signals. While control circuitry 38 is shown separately from wireless circuitry 34 in the example of FIG. 2 for the sake of clarity, wireless circuitry 34 may include processing circuitry that forms a part of processing circuitry 32 and/or storage circuitry that forms a part of storage circuitry 30 of control circuitry 38 (e.g., portions of control circuitry 38 may be implemented on wireless circuitry 34). As an example, control circuitry 38 may include baseband processor circuitry or other control components that form a part of wireless circuitry 34.

Wireless circuitry 34 may include radio-frequency (RF) transceiver circuitry formed from one or more integrated circuits, power amplifier circuitry, low-noise input amplifiers, passive RF components, one or more antennas, transmission lines, and other circuitry for handling RF wireless signals. Wireless signals can also be sent using light (e.g., using infrared communications, optical fiber communications, etc.).

Wireless circuitry 34 may include radio-frequency transceiver circuitry 36 for handling transmission and/or reception of radio-frequency signals within corresponding frequency bands at radio frequencies (sometimes referred to herein as communications bands or simply as “bands”). The frequency bands handled by radio-frequency transceiver circuitry 36 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone communications bands such as a cellular low band (LB) (e.g., 600 to 960 MHz), a cellular low-midband (LMB) (e.g., 1400 to 1550 MHz), a cellular midband (MB) (e.g., from 1700 to 2200 MHz), a cellular high band (HB) (e.g., from 2300 to 2700 MHz), a cellular ultra-high band (UHB) (e.g., from 3300 to 5000 MHz, or other cellular communications bands between about 600 MHz and about 5000 MHz), 3G bands, 4G LTE bands, 3GPP 5G New Radio Frequency Range 1 (FR1) bands below 10 GHz, 3GPP 5G New Radio (NR) Frequency Range 2 (FR2) bands between 20 and 60 GHz, other centimeter or millimeter wave frequency bands between 10-300 GHz, 3GPP 6G frequency bands (e.g., between around 100 GHz-10 THz or bands lower than 100 GHz) near-field communications frequency bands (e.g., at 13.56 MHz), satellite navigation frequency bands such as the Global Positioning System (GPS) L1 band (e.g., at 1575 MHz), L2 band (e.g., at 1228 MHz), L3 band (e.g., at 1381 MHz), L4 band (e.g., at 1380 MHz), and/or L5 band (e.g., at 1176 MHz), a Global Navigation Satellite System (GLONASS) band, a BeiDou Navigation Satellite System (BDS) band, ultra-wideband (UWB) frequency bands that operate under the IEEE 802.15.4 protocol and/or other ultra-wideband communications protocols (e.g., a first UWB communications band at 6.5 GHz and/or a second UWB communications band at 8.0 GHz), communications bands under the family of 3GPP wireless communications standards, communications bands under the IEEE 802.XX family of standards, satellite communications bands such as an L-band, S-band (e.g., from 2-4 GHz), C-band (e.g., from 4-8 GHz), X-band, Ku-band (e.g., from 12-18 GHz), Ka-band (e.g., from 26-40 GHz), etc., industrial, scientific, and medical (ISM) bands such as an ISM band between around 900 MHz and 950 MHz or other ISM bands below or above 1 GHz, one or more unlicensed bands, one or more bands reserved for emergency and/or public services, and/or any other desired frequency bands of interest. Wireless circuitry 34 may also be used to perform spatial ranging operations if desired.

As shown in FIG. 2, wireless circuitry 34 may include antennas 40. Radio-frequency transceiver circuitry 36 may convey radio-frequency signals using one or more antennas 40 (e.g., antennas 40 may convey the radio-frequency signals for the transceiver circuitry). Antennas 40 in wireless circuitry 34 may be formed using any suitable antenna structures. For example, antennas 40 may include antennas with resonating elements that are formed from stacked patch antenna structures, loop antenna structures, patch antenna structures, inverted-F antenna structures, slot antenna structures, planar inverted-F antenna structures, waveguide structures, monopole antenna structures, dipole antenna structures, helical antenna structures, Yagi (Yagi-Uda) antenna structures, hybrids of these designs, etc. If desired, antennas 40 may include antennas with dielectric resonating elements such as dielectric resonator antennas (e.g., a one dimensional array of dielectric resonator antennas aligned with region 24 of FIG. 1). If desired, one or more of antennas 40 may be cavity-backed antennas. Two or more antennas 40 may be arranged in a phased antenna array if desired (e.g., for conveying centimeter and/or millimeter wave signals within a signal beam formed in a desired beam pointing direction that may be steered/adjusted over time).

Device 10 may be provided with a dielectric cover layer (sometimes also referred to herein as a dielectric cover, device cover, or wall). The dielectric cover layer may form an exterior face of device 10 if desired. The dielectric cover layer may be a display cover layer of display 14 (FIG. 1) or a dielectric cover layer for rear housing wall 12R of device 10 (FIG. 1), as two examples. It may be desirable for the dielectric cover layer to be transparent to both visible and infrared light. For example, it may be desirable for the display cover layer of display 14 to be transparent to visible light (e.g., at wavelengths from 400-700 nm) to allow display 14 to display images through the display cover layer with minimal attenuation for view by the user. The visible light transparency of the display cover layer may also allow image sensor 16 in region 24 to capture images of visible light through the display cover layer with minimal attenuation. It may also be desirable for the display cover layer to be transparent to infrared light within region 24 to allow IR device(s) 8 to transmit IR light and/or to receive (sense) IR light through the display cover layer. However, at the same time, it may be desirable for the portion of region 24 overlapping IR device(s) 8 to be opaque to visible light to help hide IR device(s) 8, which can be unsightly, from view by the user during operation of device 10.

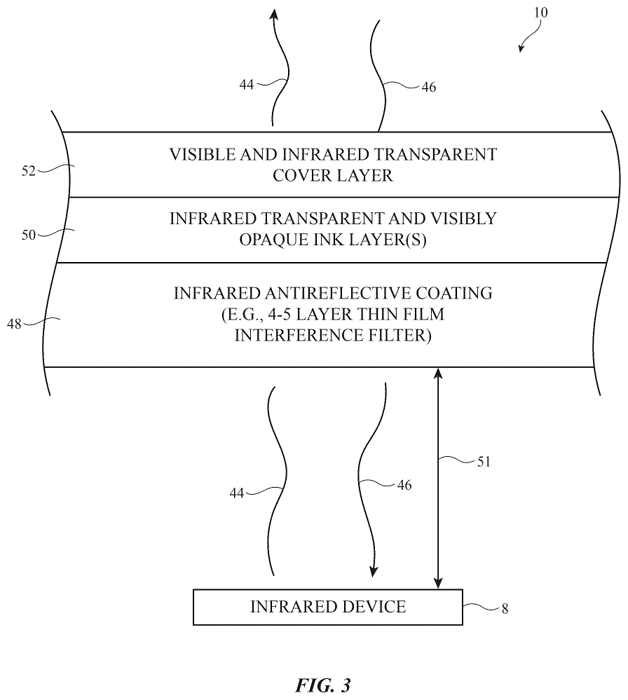

To mitigate these issues, device 10 may be provided with an IR transparent and visibly opaque coating stack on a dielectric cover layer of device 10 and overlapping IR device(s) 8. The IR transparent and visibly opaque coating stack may be transparent to IR light and may be opaque to visible light (e.g., may exhibit more transmission for IR wavelengths than visible wavelengths, may exhibit less than a first threshold amount of transmission for visible wavelengths and more than a second threshold of transmission for IR wavelengths, etc.). FIG. 3 is a cross-sectional side view of an illustrative IR transparent and visibly opaque coating stack that may be provided overlapping IR device(s) 8.

As shown in FIG. 3, device 10 may include a dielectric cover layer such as visible and IR transparent cover layer 52. Visible and IR transparent cover layer 52 may be formed from glass, sapphire, plastic, ceramic, polymer, and/or any other desired material. Visible and IR transparent cover layer 52 may, for example, transmit more than a threshold amount (e.g., 80%, 85%, 90%, 95%, 99%, 99.9%, etc.) of both visible light and infrared light. Visible and IR transparent cover layer 52 may form an exterior wall or surface of device 10 if desired. Visible and IR transparent cover layer 52 may, for example, form a display cover layer for display 14 at the front face of device 10 (FIG. 1), some or all of rear housing wall 12R at the rear face of device 10 (FIG. 1), a dielectric sidewall for device or a dielectric window in peripheral conductive housing structures 12W of device 10 (FIG. 1), etc.

Device 10 may include an IR transparent and visibly opaque coating stack layered (stacked) onto visible and IR transparent cover layer 52. The IR transparent and visibly opaque coating stack may include one or more IR transparent and visibly opaque ink layers 50 layered onto visible and IR transparent cover layer 52. If desired, the IR transparent and visibly opaque coating stack may also include an IR antireflective coating 48 layered onto IR transparent and visibly opaque ink layer(s) 50 (e.g., IR transparent and visibly opaque ink layer(s) 50 may be interposed, sandwiched, or stacked between IR antireflective coating 48 and visible and IR transparent cover layer 52). There may be one, two, three, four, five, or more than five IR transparent and visibly opaque ink layers 50 between visible and IR transparent cover layer 52 and IR antireflective coating 48. IR antireflective coating 48 may be omitted if desired. If desired, an optional black masking layer (not shown) may be included in the coating stack between IR transparent and visibly opaque ink layer(s) 50 and visible and IR transparent cover layer 52.

Each IR transparent and visibly opaque ink layer 50 may include, for example, an acrylic resin and one or more IR transmissive and visibly opaque pigments dispersed or suspended in the acrylic resin. Molecules of the pigments may each have a diameter that is less than or equal to 120 nm, 110 nm, or 100 nm, as examples. There may be one type of pigment, two types of pigments, three types of pigments, or more than three types of pigments in the acrylic resin. The pigments may collectively absorb visible light while concurrently transmitting IR light (e.g., without blocking or absorbing the IR light). This may configure IR transparent and visibly opaque ink layer(s) 50 to block or filter visible light from passing through the coating stack while concurrently transmitting IR light through the coating stack.

Depositing IR transparent and visibly opaque ink layer(s) 50 onto visible and IR transparent cover layer 52 may cause visible and IR transparent cover layer 52 to become less brittle than when an IR transparent and visibly opaque physical vapor deposition (PVD) coating (e.g., a 37 layer thin-film interference filter) is layered directly onto visible and IR transparent cover layer 52 (e.g., because the acrylic resin in IR transparent and visibly opaque ink layer(s) 50 has a lower modulus than PVD coatings). This may help to prevent damage to visible and IR transparent cover layer 52 such as cracking over time relative to implementations where a PVD coating is layered directly onto visible and IR transparent cover layer 52 during a PVD process.

IR transparent and visibly opaque ink layer 50, visible and IR transparent cover layer 52, and IR antireflective coating (ARC) 48 may overlap IR device(s) 8. IR ARC 48 may be separated from IR device(s) 8 by air gap 51. IR device(s) 8 may include one or more IR emitters that emit IR light 44 (e.g., at wavelengths greater than or equal to 700 nm) through IR ARC 48, IR transparent and visibly opaque ink layer(s) 50, and visible and IR transparent cover layer 52. Additionally or alternatively, IR device(s) 8 may include one or more IR sensors that receive IR light 46 through visible and IR transparent cover layer 52, IR transparent and visibly opaque ink layer(s) 50, and IR ARC 48. IR light 46 may include reflected IR light (e.g., a reflected version of IR light 44 that has reflected off one or more points on one or more external objects and back towards device 10) and/or may include IR light emitted by one or more IR emitters external to device 10.

Because visible and infrared transparent cover layer 52 is transparent to infrared light, IR light 46 passes through visible and IR transparent cover layer 52 to IR transparent and visibly opaque ink layer(s) 50 with minimal attenuation. Because IR transparent and visibly opaque ink layer(s) 50 are transparent to infrared light, IR light 46 then passes through IR transparent and visibly opaque ink layer(s) 50 to IR ARC 48 with minimal attenuation. Because IR ARC 48 is transparent to infrared light, IR light 46 then passes through IR ARC 48 to IR device(s) 8, which may capture images of IR light 46.

Conversely, IR ARC 48 transmits IR light 44 to IR transparent and visibly opaque ink layer(s) 50 with minimal attenuation. IR transparent and visibly opaque ink layer(s) 50 transmits IR light 44 to visible and IR transparent cover layer 52 with minimal attenuation. Visible and IR transparent cover layer 52 transmits IR light 44 to the surroundings of device 10 (e.g., free space) with minimal attenuation. In practice, there may be a relatively large difference between the refractive index of IR transparent and visibly opaque ink layer(s) 50 and air gap 51. If care is not taken, this relatively large difference in refractive index can cause an excessive amount of IR light 44 and/or IR light 46 to reflect at the interface between IR transparent and visibly opaque ink layer(s) 50 and air gap 51. The reflected IR light can interfere with other optical components in device 10, can produce undesirable cross talk of IR light 44 onto one or more IR sensors in IR device(s) 8, can produce undesirable image artifacts in the images captured by one or more IR sensors in IR device(s) 8, and/or can reduce the contrast in the images captured by one or more IR sensors in IR device(s) 8.

IR ARC 48 may serve to minimize IR light reflection between IR transparent and visibly opaque ink layer(s) 50 and air gap 51. IR ARC 48 may be, for example, a multi-layer thin-film interference filter (TFIF) that is layered onto IR transparent and visibly opaque ink layer(s) 50. The TFIF may be a coating having two or more layers that are deposited onto IR transparent and visibly opaque ink layer(s) 50. Unlike IR ARC 48, IR transparent and visibly opaque ink layer(s) 50 are not interference filters that operate via interference from reflection between layers of the filter. Instead, the optical characteristics of IR transparent and visibly opaque ink layer(s) 50 are defined by the pigment(s) in the layer(s). Since IR transparent and visibly opaque ink layer(s) 50 are already deposited onto visible and IR transparent cover layer 52 by the time IR ARC 48 is deposited onto the coating stack, the deposition of IR ARC 48 does not cause visible and IR transparent cover layer 52 to become brittle, even when deposited using a PVD process.

IR ARC 48 may be deposited on IR transparent and visibly opaque ink layer(s) 50 using any suitable deposition techniques. Examples of techniques that may be used for depositing the layers in IR ARC 48 include physical vapor deposition (PVD) (e.g., evaporation and/or sputtering), cathodic arc deposition, chemical vapor deposition, ion plating, laser ablation, etc. IR ARC may form a TFIF that includes a stack of two or more layers of material such as inorganic dielectric layers with different index of refraction values. The layers in the TFIF may have higher index of refraction values (sometimes referred to as “high” index values) and lower index of refraction values (sometimes referred to as “low” index values). The high index layers may be interleaved with the low index layers if desired. Incident light may be transmitted through each of the layers in the TFIF while also reflecting off the interfaces between each of the layers, as well as at the interface between the TFIF and IR transparent and visibly opaque ink layer(s) 50 and at the interface between the TFIF and air gap 51. By controlling the thickness and index of refraction (e.g., composition) of each layer in the TFIF, the light reflected at each interface may destructively interfere to minimize the amount of reflected IR light passed back to IR device(s) 8 and/or to the surroundings.

Because visible and IR transparent cover layer 52 is transparent to visible light, display circuitry in device 10 (e.g., in display 14 of FIG. 1) may display light through a portion of visible and IR transparent cover layer 52 that is non-overlapping with respect to IR transparent and visibly opaque ink layer(s) 50 and IR ARC 48 with minimal attenuation. At the same time, because IR transparent and visibly opaque ink layer(s) 50 are opaque (non-transparent) to visible light, IR transparent and visibly opaque ink layer(s) 50 may prevent, stop, or block visible light that otherwise passes through visible and IR transparent cover layer 52 from the surroundings of device 10. This may prevent the visible light from passing into the interior of device 48 and then reflecting off of components at the interior of device 10 (e.g., IR device(s) 8) and back through visible and IR transparent cover layer 52, where the reflected visible light would otherwise be viewable by an observer. This may serve to hide IR device(s) 8 and other components at the interior of device 10 from being easily viewed or perceived by a user, providing device 10 with an attractive cosmetic appearance.

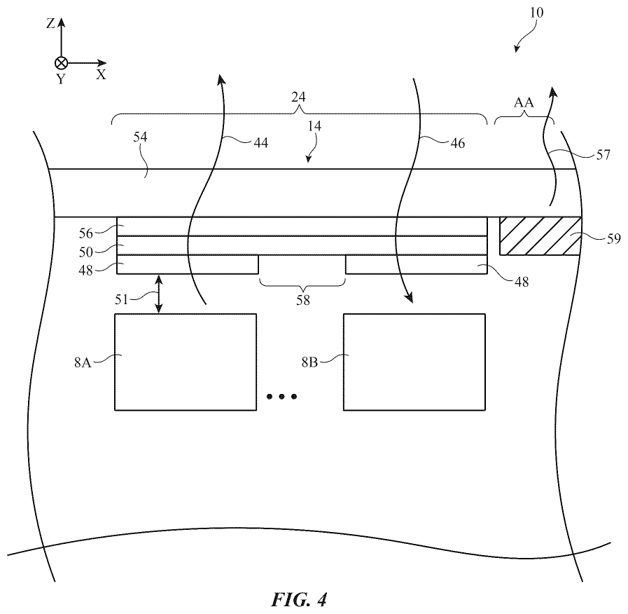

FIG. 4 is a cross-sectional side view of device 10 (e.g., as taken in the direction of line BB′ of FIG. 1) showing one example of how the IR transparent and visibly opaque coating stack of FIG. 3 may be layered onto region 24 of display 14. As shown in FIG. 4, display 14 may include a display cover layer 54. Display cover layer 54 may form visible and IR transparent cover layer 52 of FIG. 3. Display 14 may include pixel circuitry 59 in active area AA (i.e., outside of region 24). Pixel circuitry 59 may emit visible light 57. Display cover layer 54 may transmit visible light 57 from the pixel circuitry to the exterior of device 10 with minimal attenuation.

The IR device(s) 8 in device 10 may include one or more IR emitters 8A and/or one or more IR sensors 8B overlapping region 24 of display 14. IR emitter(s) 8A may emit IR light 44 through the IR transparent and visibly opaque coating stack and through display cover layer 54 within region 24. IR emitter(s) 8A are sometimes also referred to herein as IR light source(s) 8A. IR sensor(s) 8B may receive IR light 46 through display cover layer 54 and the IR transparent and visibly opaque coating stack within region 24.

The IR transparent and visibly opaque coating stack may be layered onto the interior surface of display cover layer 54. The IR transparent and visibly opaque coating stack may be separated from IR sensor(s) 8B and IR emitter(s) 8A by air gap 51. The IR transparent and visibly opaque coating stack may include an optional black mask layer 56 layered onto the interior surface of display cover layer 54. The IR transparent and visibly opaque coating stack may include IR transparent and visibly opaque ink layer(s) 50 layered onto black mask layer 56. The IR transparent and visibly opaque coating stack may include IR ARC 48 layered onto IR transparent and visibly opaque ink layer(s) 50.

As shown in FIG. 4, IR ARC 48 may be patterned onto IR transparent and visibly opaque ink layer(s) 50 such that there is at least one gap 58 that separates a first region of IR ARC 48 from a second region of IR ARC 48. The first region may overlap IR emitter(s) 8A. The second region may overlap IR sensor(s) 8B. Gap 58 may be non-overlapping with respect to IR emitter(s) 8A and IR sensor(s) 8B. IR ARC 48 may help to minimize IR light reflection at the interface between air gap 51 and IR transparent and visibly opaque ink layer(s) 50. Gap 58 may help to further minimize undesirable IR cross talk between IR emitter(s) 8A and IR sensor(s) 8B.

If desired, black mask layer 56 may include a ring of black masking material (e.g., ink or other visibly opaque materials) that laterally surrounds an opening that is free from black masking material. The opening may overlap IR emitter(s) 8A and IR sensor(s) 8B. IR transparent and visibly opaque ink layer(s) 50 may allow IR light 44 and 46 to pass through region 24 of display 14 while concurrently blocking visible light from passing through region 24 of display 14, helping to hide the interior of device 10 from view. If desired, the IR transparent and visibly opaque coating stack may be non-overlapping with respect to one or more visible light components overlapping region 24 of display 14 (e.g., image sensor 16 of FIG. 1) so as to allow visible light to pass through display 14 for those visible light components.

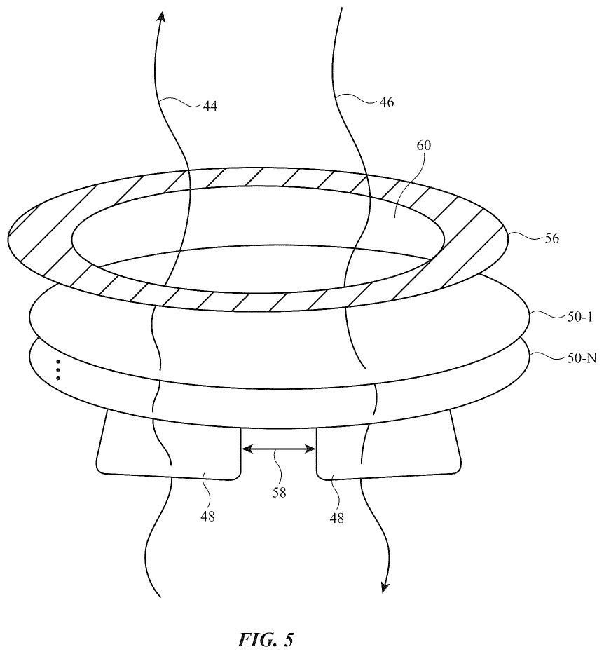

FIG. 5 is an exploded perspective view of the IR transparent and visibly opaque coating stack of FIG. 4. In the example of FIG. 5, display cover layer 54, IR emitter(s) 8A, and IR sensor(s) 8B have been omitted for the sake of clarity. As shown in FIG. 5, the IR transparent and visibly opaque coating stack may include N IR transparent and visibly opaque ink layers 50 between black mask layer 56 and IR ARC 48. N may be equal to one, two, three, four, five, or more than five. In general, a greater number of IR transparent and visibly opaque ink layers 50 may serve to increase the opacity of the IR transparent and visibly opaque coating stack to visible light.

Black mask layer 56 may include a ring of masking material that laterally surrounds a central opening such as opening 60. Opening 60 may overlap IR emitter(s) 8A and IR sensor(s) 8B (FIG. 4). Black mask layer 56 may be omitted if desired. Gap 58 may separate a first region of IR ARC 48 from a second region of IR ARC 48. IR light 44 may pass through the first region of IR ARC 48, through the N IR transparent and visibly opaque ink layers 50, and through the opening of black mask layer 56. Conversely, IR light 46 may pass through the opening of black mask layer 56, the N IR transparent and visibly opaque ink layers 50, and the second region of IR ARC 48.

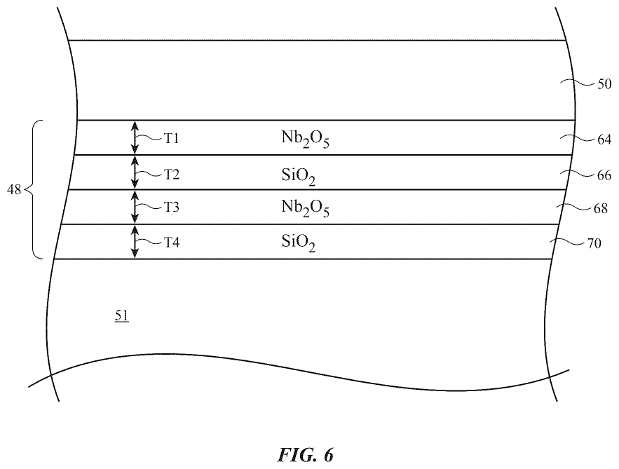

FIG. 6 is a cross-sectional side view showing one example of how IR ARC 48 may be implemented as a multi-layer TFIF. In the example of FIG. 6, IR ARC 48 is a four-layer interference filter having a first layer 64 layered onto IR transparent and visibly opaque ink layer(s) 50, a second layer 66 layered onto layer 64, a third layer 68 layered onto layer 66, and a fourth layer 70 layered onto layer 68. Layer 70 may be a lowermost (bottom) layer of IR ARC 48. Layer 68 may be a second lowermost layer of IR ARC 48. Layer 66 may be a second uppermost layer of IR ARC 48. Layer 64 may be an uppermost (top) layer of IR ARC 48. Layers 64-70 may have alternating high and low refractive indices.

Layer 64 may include niobium (Nb) and oxygen (O) (e.g., niobium oxide (Nb₂O₅)) and may sometimes also be referred to herein as Nb₂O₅ layer 64. Layer 66 may include silicon (Si) and O (e.g., silicon dioxide (SiO₂)) and may sometimes also be referred to herein as SiO₂ layer 66. Layer 68 may include Nb and O (e.g., Nb₂O₅) and may sometimes also be referred to herein as Nb₂O₅ layer 68. Layer 70 may include Si and O (e.g., SiO₂) and may sometimes also be referred to herein as SiO₂ layer 70. This example is illustrative and non-limiting. If desired, IR ARC 48 may include five layers, more than five layers, three layers, two layers, or a single layer. The layer(s) of IR ARC 48 may include Nb₂O₅, SiO₂, titanium dioxide (TiO₂), aluminum oxide (Al₂O₃), other metals, other non-metals, other oxides, and/or any other desired materials.

Layer 64 may have thickness T1. Layer 66 may have thickness T2. Layer 68 may have thickness T3. Layer 70 may have thickness T4. Thicknesses T1-T4 and the compositions of layers 64-70 may be selected to impart IR ARC 48 with desired interference effects to minimize the amount of reflected IR light produced at the interface between IR transparent and visibly opaque ink layer(s) 50 and air gap 51.

Thickness T1 may be, for example, 40-50 nm, 45-50 nm, 45-55 nm, 30-60 nm, 20-70 nm, greater than 45 nm, greater than 40 nm, greater than 30 nm, less than 50 nm, less than 60 nm, less than 100 nm, or other thicknesses. Thickness T2 may be, for example, 30-40 nm, 30-35 nm, 20-50 nm, 10-50 nm, greater than 30 nm, greater than 20 nm, greater than 10 nm, less than 40 nm, less than 50 nm, less than 100 nm, less than thickness T1, or other thicknesses. Thickness T3 may be, for example, 120-130 nm, 110-140 nm, 100-150 nm, 125-130 nm, greater than 120 nm, greater than 110 nm, greater than 100 nm, less than 130 nm, less than 140 nm, less than 150 nm, greater than thickness T1, or other thicknesses. Thickness T4 may be, for example, 170-180 nm, 170-175 nm, 160-190 nm, 150-200 nm, greater than 170 nm, greater than 160 nm, greater than 150 nm, less than 180 nm, less than 200 nm, less than 250 nm, greater than thickness T3, or other thicknesses.

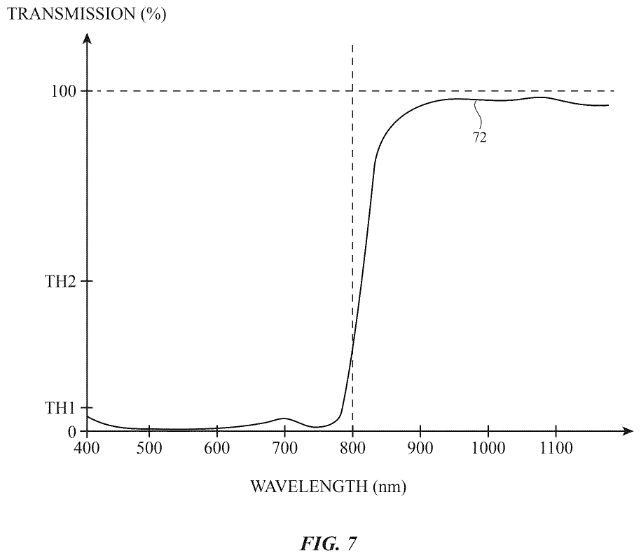

Curve 72 of FIG. 7 plots the amount of light transmission by an IR transparent and visibly opaque ink layer 50 in device 10 as a function of wavelength. The pigment(s) in the IR transparent and visibly opaque ink layer may collectively configure the IR transparent and visibly opaque ink layer to exhibit an optical transmission profile characterized by curve 72. As shown by curve 72, IR transparent and visibly opaque ink layer 50 may exhibit relatively low transmission at visible wavelengths less than 700 nm and may exhibit relatively high transmission at IR wavelengths greater than 700 nm.

For example, as shown in FIG. 7, IR transparent and visibly opaque ink layer 50 may exhibit an optical transmission less than a first threshold TH1 at wavelengths less than or equal to 700 nm, 750 nm, or another wavelength between 700 nm and 750 nm. Threshold TH1 may be 10%, 5%, 2%, 1%, 1-10%, 1-5%, 0.5%, 0.5-5%, 3%, 6%, or other values. At the same time, IR transparent and visibly opaque ink layer 50 may exhibit an optical transmission greater than a second threshold TH2 at wavelengths greater than or equal to 700 nm, 750 nm, 800 nm, or another wavelength between 700 nm and 800 nm. Threshold TH2 may be 50%, 60%, 50-70%, 40-80%, 50-90%, 60-90%, 70%, 80%, 90%, 95%, 99%, 99.5%, 80-99.5%, 80-90%, 80-95%, 90-95%, 96%, 85%, 88%, 89%, 91%, 75-90%, or other values. Curve 72 may have other shapes in practice.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

Device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is illustrative and various modifications can be made by those skilled in the art without departing from the scope and spirit of the described embodiments. The foregoing embodiments may be implemented individually or in any combination.

What is claimed is:

1. An electronic device comprising:
an infrared device configured to operate on infrared light;
a dielectric cover layer overlapping the infrared device, the dielectric cover layer being configured to transmit the infrared light and visible light;
an ink layer on the dielectric cover layer and overlapping the infrared device, the ink layer being configured to transmit the infrared light and being configured to absorb the visible light; and
a thin film interference filter (TFIF) on the ink layer and overlapping the infrared device, the ink layer being interposed between the TFIF and the dielectric cover layer.

2. The electronic device of claim 1, further comprising:
an additional ink layer interposed between the ink layer and the TFIF, the additional ink layer being configured to transmit the infrared light and being configured to absorb the visible light.

3. The electronic device of claim 1, wherein the ink layer comprises an acrylic resin and at least one pigment dispersed in the acrylic resin.

4. The electronic device of claim 3, wherein the at least one pigment configures the ink layer to exhibit less than 10% transmission at wavelengths less than or equal to 700 nm and configures the ink layer to exhibit greater than 50% transmission at wavelengths greater than or equal to 750 nm.

5. The electronic device of claim 1, wherein the TFIF is configured to form an antireflective coating for the infrared light.

6. The electronic device of claim 1, wherein the TFIF comprises a first layer on the ink layer, a second layer on the first layer, a third layer on the second layer, and a fourth layer on the third layer.

7. The electronic device of claim 6, wherein the first and third layers comprise Nb₂O₅ and wherein the second and fourth layers comprise SiO₂.

8. The electronic device of claim 6, wherein the first and third layers comprise a material selected from the group consisting of: Nb₂O₅, SiO₂, TiO₂, and Al₂O₃.

9. The electronic device of claim 1, wherein the infrared device comprises an infrared emitter configured to emit the infrared light through the TFIF, the ink layer, and the dielectric cover layer.

10. The electronic device of claim 1, wherein the infrared device comprises an infrared sensor configured to receive the infrared light through the TFIF, the ink layer, and the dielectric cover layer.

11. The electronic device of claim 10, wherein the infrared device further comprises an infrared emitter configured to emit the infrared light through the TFIF, the ink layer, and the dielectric cover layer.

12. The electronic device of claim 11, further comprising:
a gap that separates a first region of the TFIF from a second region of the TFIF, wherein the first region of the TFIF overlaps the IR sensor and the second region of the TFIF overlaps the IR emitter.

13. The electronic device of claim 1, further comprising:
a display that includes the dielectric cover layer; and
pixel circuitry configured to display visible light through the dielectric cover layer, wherein the display includes an inactive region laterally surrounded by the pixel circuitry, and wherein the ink layer, the TFIF, and the IR device overlap the inactive region.

14. The electronic device of claim 1, further comprising:
a ring-shaped black masking layer interposed between the ink layer and the dielectric cover layer, wherein the ring-shaped black masking layer has an opening that overlaps the infrared device.

15. Apparatus comprising:
a substrate that is transparent to visible light and infrared light;
an ink layer on the substrate and including one or more pigments that configure the ink layer to be transparent to the infrared light and opaque to the visible light; and
an infrared antireflective coating on the ink layer, the ink layer being interposed between the substrate and the infrared antireflective coating.

16. The apparatus of claim 15, wherein the infrared antireflective coating comprises:
a first layer on the ink layer;
a second layer on the first layer;
a third layer on the second layer; and
a fourth layer on the third layer.

17. The apparatus of claim 16, wherein the first and third layers comprise Nb₂O₅ and wherein the third and fourth layers comprise SiO₂.

18. The apparatus of claim 15, further comprising:
an infrared emitter configured to emit the infrared light through the infrared antireflective coating, the ink layer, and the substrate.

19. An electronic device comprising:
a display having a display cover layer and pixel circuitry configured to display images through the display cover layer, wherein the pixel circuitry laterally surrounds an inactive island in the display;
an infrared transparent and visibly opaque ink layer on the display cover layer and overlapping the inactive island;
an infrared emitter overlapping the inactive island and configured to emit first infrared light through the infrared transparent and visibly opaque ink layer and the display cover layer; and
an infrared sensor overlapping the inactive island and configured to receive second infrared light through the display cover layer and the infrared transparent and visibly opaque ink layer.

20. The electronic device of claim 19, further comprising:
a ring-shaped black masking layer interposed between the display cover layer and the infrared transparent and visibly opaque ink layer, wherein the ring-shaped black masking layer has an opening that overlaps the infrared emitter and the infrared sensor;
a first Nb₂O₅ layer on the infrared transparent and visibly opaque ink layer;
a first SiO₂ layer on the first Nb₂O₅ layer;
a second Nb₂O₅ layer on the first SiO₂ layer;
a second SiO₂ layer on the second Nb₂O₅ layer; and
a gap that separates a first region of the first Nb₂O₅ layer, the first SiO₂ layer, the second Nb₂O₅ layer, and the second SiO₂ layer from a second region of the first Nb₂O₅ layer, the first SiO₂ layer, the second Nb₂O₅ layer, and the second SiO₂ layer, wherein the first region overlaps the infrared emitter and the second region overlaps the infrared sensor.
